(19) United States
(12) Patent Application Publication
(10) Pub. No.: US 2024/0375586 A1
(43) Pub. Date: Nov. 14, 2024

(54) VEHICULAR MIRROR ASSEMBLY WITH THERMAL AND SOUND INSULATOR

(71) Applicant: Magna Mirrors of America, Inc., Holland, MI (US)

(72) Inventors: Anthony J. LaCross, Hastings, MI (US); Austen C. Peterson, Hudsonville, MI (US)

(21) Appl. No.: 18/659,106

(22) Filed: May 9, 2024

Related U.S. Application Data
(60) Provisional application No. 63/501,698, filed on May 12, 2023.

(51) Int. Cl. B60R 1/04; B60R 1/08; B60R 1/12; B60R 1/26; H05K 7/20

(52) U.S. Cl. CPC B60R 1/04; B60R 1/08; B60R 1/12; B60R 1/26; H05K 7/20154; B60R 2001/1253

(57) ABSTRACT

A vehicular interior rearview mirror assembly includes a mirror head adjustable about a mounting structure configured to mount the mirror assembly at an interior portion of a cabin of a vehicle. The mirror head accommodates an electronic component. When the electronic component is electrically operated, the electronic component generates heat within an interior cavity of the mirror head. An aerogel-infused material is disposed within the interior cavity of the mirror head and thermally conductively connects the electronic component with at least a portion of the mirror casing. The aerogel-infused material, when the electronic component is electrically operated and generates heat within the interior cavity of the mirror head, reduces thermal transfer between the electronic component and at least the portion of the mirror casing.

### CROSS REFERENCE TO RELATED APPLICATION

The present application claims the filing benefits of U.S. provisional application Ser. No. 63/501,698, filed May 12, 2023, which is hereby incorporated herein by reference in its entirety.

### FIELD OF THE INVENTION

The present invention relates generally to the field of interior rearview mirror assemblies for vehicles.

### BACKGROUND OF THE INVENTION

It is known to provide a mirror assembly that is adjustably mounted to an interior portion of a vehicle, such as via a double ball pivot or joint mounting configuration where the mirror casing and reflective element are adjusted relative to the interior portion of a vehicle by pivotal movement about the double ball pivot configuration. The mirror casing and reflective element are pivotable about either or both of the ball pivot joints by a user that is adjusting a rearward field of view of the reflective element.

### SUMMARY OF THE INVENTION

An interior rearview mirror assembly for a vehicle includes a mirror head adjustably attached to a mounting structure. The mounting structure is configured to attach at an interior portion of a cabin of a vehicle equipped with the interior rearview mirror assembly. The mirror head includes a mirror casing accommodating a mirror reflective element. One or more heat generating components are accommodated by the mirror head. When the one or more heat generating electronic components are electrically operated, the one or more heat generating electronic components generate heat at an interior of the mirror head. An aerogel-infused material is disposed at the interior of the mirror casing and is in thermally conductive connection between the one or more heat generating electronic components and at least a portion of the mirror casing. When the one or more heat generating electronic components generate heat at the interior of the mirror head, the aerogel-infused material at least partially prevents heat generated by the one or more heat generating electronic components from thermally transferring to at least the portion of the mirror casing. The aerogel material also provides sound deadening properties.

These and other objects, advantages, purposes and features of the present invention will become apparent upon review of the following specification in conjunction with the drawings.

### BRIEF DESCRIPTION OF THE DRAWINGS

FIG. 1 is a perspective view of an interior rearview mirror assembly;

FIG. 2 is a sectional diagram of the mirror head of the interior rearview mirror assembly, showing a thermally insulating aerogel material that prevents or reduces thermal transfer between a heat sink at the interior of the mirror head and the mirror casing; and

FIG. 3 is a sectional diagram of the mirror head, showing an audio insulating material that prevents or reduces transfer of vibration and/or sound from the mirror head.

### DESCRIPTION OF THE PREFERRED EMBODIMENTS

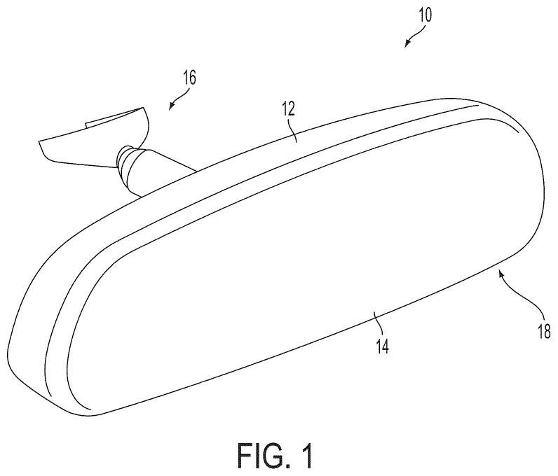

Referring now to the drawings and the illustrative embodiments depicted therein, an interior rearview mirror assembly 10 for a vehicle includes a mirror head 18 that includes a casing 12 and a reflective element 14 positioned at a front portion of the casing 12 (FIG. 1). In the illustrated embodiment, the mirror assembly 10 is configured to be adjustably mounted to an interior portion of an interior cabin of a vehicle (such as to an interior or in-cabin surface of a vehicle windshield or a headliner of a vehicle or the like) via a mounting structure or mounting configuration or assembly 16. The mirror reflective element 14 comprises a variable reflectance mirror reflective element that varies its reflectance responsive to electrical current applied to conductive coatings or layers of the reflective element.

As discussed further below, the mirror assembly 10 includes one or more electrically operable and heat generating components at an interior of the mirror head 18 that, when electrically operated, generates heat at the interior of the mirror head 18. For example, the mirror reflective element 14 may include a video display screen that is electrically operable to display video images (e.g., video images derived from image data captured by a rearward viewing camera at the vehicle) for viewing by the driver of the vehicle. The video display screen is disposed within the mirror head 18 behind a mirror reflector of the mirror reflective element 14 and, when electrically operated, emits light that is visible through the mirror reflective element 14 (such as through a transflective mirror reflector of the mirror reflective element). Optionally, one or more cameras (such as a driver monitoring camera for a driver monitoring system (DMS) of the vehicle) may be disposed within the mirror head 18 and may view an interior portion of the cabin of the vehicle (such as through the mirror reflective element). Optionally, the DMS may include an infrared or near infrared light emitter (or two or more light emitters) that is electrically operable to emit infrared or near infrared light through the mirror reflective element 14 to illuminate at least a portion (e.g., a driver seat region) of the vehicle cabin. The mirror head 18 may accommodate electronic circuitry (e.g., a printed circuit board (PCB) having one or more image and/or data processors) for operating the DMS and/or one or more advanced driving assistance systems (ADAS) of the vehicle. Further, the mirror assembly 10 may include an electrically operable actuator that is electrically operable to pivot the mirror head 18 relative to the mounting assembly 16 to adjust the view provided by the mirror reflective element 14 to the driver, and one or more other electronic components.

When the one or more electrically operable components are electrically operated, heat is generated at the interior of the mirror head 18 and the heat may be dissipated to the environment (e.g., the vehicle cabin), such as through the mirror casing 12 (such as through vents or ducts in the mirror casing or such as via heat dissipating fins at the mirror casing). However, the mirror casing 12 may become hot to the touch, which may make it difficult or uncomfortable for the driver to manually adjust the position of the mirror head 18 relative to the mounting structure 16.

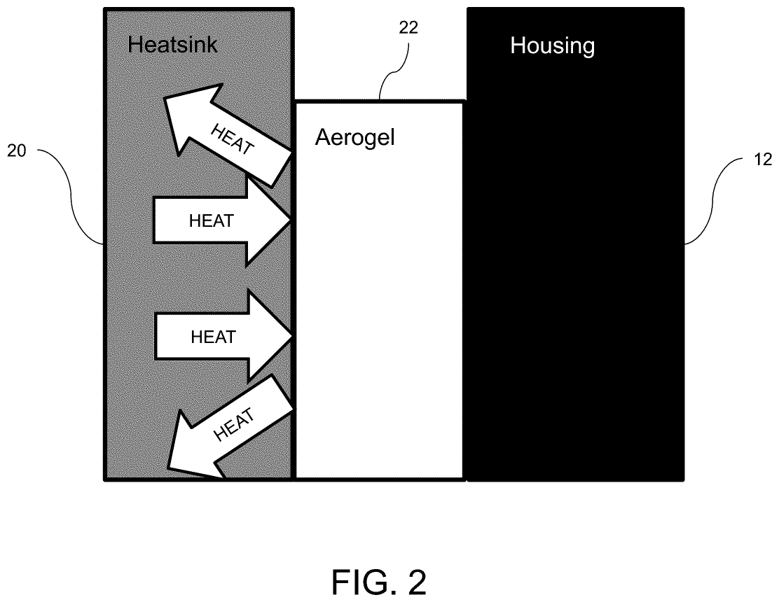

Thus, and as shown in FIG. 2, a heat sink 20 may be in thermally conductive connection with the one or more heat generating components at the interior of the mirror head 18. For example, the heat sink 20 may be disposed at a rear side of a PCB, where the opposite front side of the PCB accommodates the one or more heat generating components. The heat sink 20 absorbs and/or dissipates the heat from the one or more heat generating components. That is, as the one or more heat generating components are electrically operated and generate heat, the heat is dissipated to the heat sink 20 and away from the heat generating component. To prevent the heat sink 20 from transferring heat to the mirror casing 12, an aerogel-infused material or layer 22 is positioned between the heat sink 20 and the inner surface of the mirror casing 12.

For example, the aerogel may be used as a composite in the form of a foam, a paint, an adhesive, a plastic, or any other suitable form. The aerogel material is derived from a gel, yet provides a lightweight porous material because it is formed by replacing the liquid component of the gel with a gas. Because aerogel material blocks or reduces heat transfer (and sound transfer), the aerogel-infused layer 22 prevents or reduces the thermal transfer between the heat sink 20 and/or heat generating components and the mirror casing 12.

Heat generated by the one or more components may then be dissipated from the housing via other means, such as a cooling fan that directs cooling air along and between heat dissipating fins of the heat sink 20. Optionally, the aerogel layer 22 may be strategically positioned to block or reduce thermal transfer at some positions or portions of the mirror casing 12 and to allow thermal transfer at other positions (i.e., positions where the aerogel layer is not disposed between the heat sink or heat generating component and the mirror casing). For example, the aerogel layer 22 may be positioned between the heat generating components and the mirror casing 12 along the respective sides of the mirror head (e.g., where the driver may be likely to grasp the mirror casing) and the aerogel layer 22 may not be positioned between the heat generating components and the mirror casing 12 at a central portion of the mirror head (e.g., where the driver may be unlikely to grasp the mirror casing). Thus, the aerogel-infused material 22 is disposed within the mirror head at or near heat generating electronic components to prevent or preclude or reduce thermal transfer between the components and an outer surface of the mirror head (such as a touch surface of the mirror head).

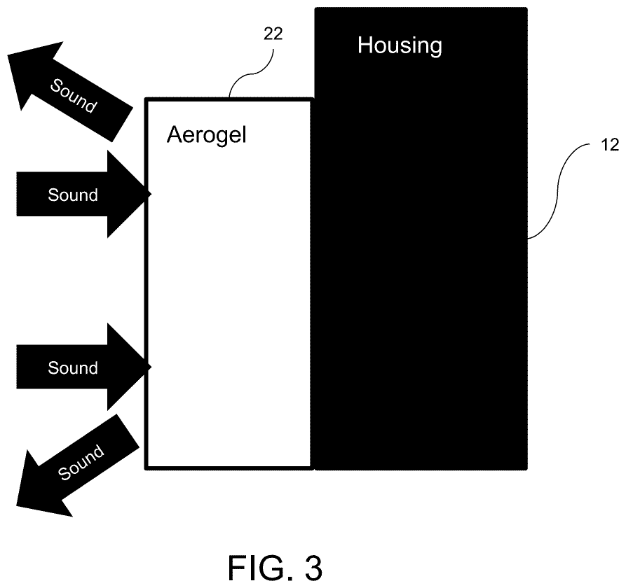

As shown in FIG. 3, because aerogel has sound deadening qualities, the aerogel-infused material 22 may be disposed within the mirror head at or near sound or vibration generating components to prevent or preclude or reduce noise and vibration levels caused by operation of the sound or vibration generating components. For example, a cooling fan or an actuator with an electrically operable motor may be disposed within the mirror head 18 and generate sound and/or vibration when operated. Thus, the inner surface of the mirror casing 12 may be coated or layered with the aerogel-infused material 22 to reduce sound or vibration exiting the mirror head 18. Optionally, a surface of the actuator and/or cooling fan (or other sound generating component) may be coated with the aerogel-infused material.

Although discussed herein with respect to the interior rearview mirror assembly of the vehicle, it should be understood that aspects of the mirror assembly and aerogel-infused material or layer may be utilized with any suitable vehicular component, such as an exterior rearview mirror assembly or powerfold exterior rearview mirror assembly, a door handle assembly for opening a side door and/or liftgate of the vehicle, a pivotable headlamp or corresponding cover, an extendable/retractable exterior camera or camera wing, a charge port or fuel port cover panel assembly, and the like.

For example, the vehicular component (e.g., exterior powerfold mirror assembly or door handle assembly or charge port cover panel assembly, and the like) may include an actuator with an electrically operable motor that operates to move the component relative to the vehicle. When the motor and actuator operate, the actuator may generate heat and/or noise or vibration. Traditionally, to meet noise requirements, the maximum operating power of the actuator may be reduced and thus performance may be sacrificed for reduced noise. However, with the aerogel-infused material disposed at or near or in or around the vehicular component and the actuator (such as between the actuator and a housing of the vehicular component), the level of noise escaping the vehicular component is reduced. Thus, the performance of the actuator may be improved without sacrificing desired noise levels.

Thus, the aerogel material may be used a thermal insulator. For example, a strip of aerogel-infused material (e.g., a foam, a paint, an adhesive, a plastic material and the like) may be placed between the housing and a heat sink to prevent thermal transfer between the heatsink and the housing. The use of the aerogel material reduces the temperature of touch points or contact points at the outer surface that may be contacted by a user or driver of the vehicle. This prevents injury or discomfort to the driver, such as during adjustment of the mirror head, and allows for higher performance of electronic components within the mirror head without drastically increasing temperature at the outer surface of the mirror head. For example, the video display screen of the mirror head may be driven or operated in a brighter state without throttling performance and still maintaining a cooler outer surface.

Further, the aerogel material may be used as a sound insulator. For example, the aerogel-infused material may be coated and/or layered along the inside of the mirror, such as along an inner surface of the mirror casing. Thus, if the mirror includes a cooling fan or cooling mechanism or actuator or other sound or vibration generating component, the aerogel provides sound deadening qualities that can be used to decrease noise intrusion into the cabin of the vehicle and improve perceived quality.

Although described herein as suitable for use with an interior rearview mirror assembly, it should be understood that the aerogel-infused component may be suitable for use with other vehicular components, such as a powerfold exterior rearview mirror assembly, a flush door handle assembly, a charge port or fuel port door cover panel assembly, an extendable/retractable exterior camera wing assembly, or any other vehicular component that uses an actuator to move between positions relative to the vehicle. The aerogel-infused material may be coated and/or layered at the inside of the actuator housing. Thus, if the vehicular component includes a sound or vibration generating element, such as a motor or other moving mechanism or electrical or mechanical vibrating element, the aerogel provides sound deadening qualities that can be used to improve perceived quality and decrease the sound emitted by these electro-mechanical systems. Decreasing vibration can improve the performance and usability of the systems. Further, the aerogel material may help the component achieve noise requirements as blocking out emitted sound allows these systems (e.g., the actuators of these components) to be driven more aggressively while achieving similar or improved sound levels and performance.

The interior mirror assembly comprises a dual-mode interior rearview video mirror that can switch from a traditional reflection mode to a live-video display mode, such as is by utilizing aspects of the mirror assemblies and systems described in U.S. Pat. Nos. 11,242,008; 11,214,199; 10,442,360; 10,421,404; 10,166,924; 10,046,706 and/or 10,029,614, and/or U.S. Publication Nos. US-2021-0162926; US-2021-0155167; US-2020-0377022; US-2019-0258131; US-2019-0146297; US-2019-0118717 and/or US-2017-0355312, which are all hereby incorporated herein by reference in their entireties. The video display screen of the video mirror, when the mirror is in the display mode, may display video images derived from video image data captured by a rearward viewing camera, such as a rearward camera disposed at a center high-mounted stop lamp (CHMSL) location, and/or video image data captured by one or more other cameras at the vehicle, such as side-mounted rearward viewing cameras or the like, such as by utilizing aspects of the display systems described in U.S. Pat. No. 11,242,008, which is hereby incorporated herein by reference in its entirety.

The reflective element and mirror casing are adjustable relative to a base portion or mounting assembly to adjust the driver's rearward field of view when the mirror assembly is normally mounted at or in the vehicle. The mounting assembly may comprise a single-ball or single-pivot mounting assembly, whereby the reflective element and casing are adjustable relative to the vehicle windshield (or other interior portion of the vehicle) about a single pivot joint, or the mounting assembly may comprise other types of mounting configurations, such as a double-ball or double-pivot mounting configuration or the like. The socket or pivot element is configured to receive a ball member of the base portion, such as for a single pivot or single ball mounting structure or a double pivot or double ball mounting structure or the like (such as a pivot mounting assembly of the types described in U.S. Pat. Nos. 6,318,870; 6,593,565; 6,690,268; 6,540,193; 4,936,533; 5,820,097; 5,100,095; 7,249,860; 6,877,709; 6,329,925; 7,289,037; 7,249,860 and/or 6,483,438, which are hereby incorporated herein by reference in their entireties).

The mounting base includes an attaching portion that is configured to be attached to an interior surface of a vehicle windshield (such as to a mounting button or attachment element adhered to the interior surface of the vehicle windshield or such as to a headliner or overhead console of the vehicle). The mounting base may comprise a metallic ball portion or may comprise a molded (such as injection molded) polymeric mounting base or may be otherwise formed, depending on the particular application of the mirror assembly.

The mirror assembly may comprise any suitable construction, such as, for example, a mirror assembly with the reflective element being nested in the mirror casing and with a bezel portion that circumscribes a perimeter region of the front surface of the reflective element, or with the mirror casing having a curved or beveled outermost exposed perimeter edge around the reflective element and with no overlap onto the front surface of the reflective element (such as by utilizing aspects of the mirror assemblies described in U.S. Pat. Nos. 7,184,190; 7,274,501; 7,255,451; 7,289,037; 7,360,932; 7,626,749; 8,049,640; 8,277,059 and/or 8,529,108, which are hereby incorporated herein by reference in their entireties) or such as a mirror assembly having a rear substrate of an electro-optic or electrochromic reflective element nested in the mirror casing, and with the front substrate having a curved or beveled outermost exposed perimeter edge, or such as a mirror assembly having a prismatic reflective element that is disposed at an outer perimeter edge of the mirror casing and with the prismatic substrate having a curved or beveled outermost exposed perimeter edge, such as described in U.S. Pat. Nos. 9,827,913; 9,174,578; 8,508,831; 8,730,553; 9,598,016 and/or 9,346,403, and/or U.S. Des. Pat. Nos. D633,423; D633,019; D638,761 and/or D647,017, which are hereby incorporated herein by reference in their entireties (and with electrochromic and prismatic mirrors of such construction are commercially available from the assignee of this application under the trade name INFINITY™ mirror).

As discussed above, the mirror assembly may comprise an electro-optic or electrochromic mirror assembly that includes an electro-optic or electrochromic reflective element. The perimeter edges of the reflective element may be encased or encompassed by the perimeter element or portion of the bezel portion to conceal and contain and envelop the perimeter edges of the substrates and the perimeter seal disposed therebetween. The electrochromic mirror element of the electrochromic mirror assembly may utilize the principles disclosed in commonly assigned U.S. Pat. Nos. 7,274,501; 7,255,451; 7,195,381; 7,184,190; 6,690,268; 5,140,455; 5,151,816; 6,178,034; 6,154,306; 6,002,544; 5,567,360; 5,525,264; 5,610,756; 5,406,414; 5,253,109; 5,076,673; 5,073,012; 5,117,346; 5,724,187; 5,668,663; 5,910,854; 5,142,407 and/or 4,712,879, which are hereby incorporated herein by reference in their entireties.

The mirror assembly may include a camera or sensor or light of a driver monitoring system and/or head and face direction and position tracking system and/or eye tracking system and/or gesture recognition system. Such head and face direction and/or position tracking systems and/or eye tracking systems and/or gesture recognition systems may utilize aspects of the systems described in U.S. Pat. Nos. 11,582,425; 11,518,401; 10,958,830; 10,065,574; 10,017,114; 9,405,120 and/or 7,914,187, and/or U.S. Publication Nos. US-2022-0377219; US-2022-0254132; US-2022-0242438; US-2021-0323473; US-2021-0291739; US-2020-0320320; US-2020-0202151; US-2020-0143560; US-2019-0210615; US-2018-0231976; US-2018-0222414; US-2017-0274906; US-2017-0217367; US-2016-0209647; US-2016-0137126; US-2015-0352953; US-2015-0296135; US-2015-0294169; US-2015-0232030; US-2015-0092042; US-2015-0022664; US-2015-0015710; US-2015-0009010 and/or US-2014-0336876, and/or U.S. patent application Ser. No. 18/508,351, filed Nov. 14, 2023 (Attorney Docket DON01 P4996), and/or U.S. patent application Ser. No. 18/535,183, filed Dec. 11, 2023 (Attorney Docket MAG04 P5021), and/or International Publication Nos. WO 2023/220222; WO 2023/034956; WO 2022/241423 and/or WO 2022/187805, which are hereby incorporated herein by reference in their entireties.

Optionally, the driver monitoring system may be integrated with a camera monitoring system (CMS) of the vehicle. The integrated vehicle system incorporates multiple inputs, such as from the inward viewing or driver monitoring camera and from the forward or outward viewing camera, as well as from a rearward viewing camera and sideward viewing cameras of the CMS, to provide the driver with unique collision mitigation capabilities based on full vehicle environment and driver awareness state. The image processing and detections and determinations are performed locally within the interior rearview mirror assembly and/or the overhead console region, depending on available space and electrical connections for the particular vehicle application. The CMS cameras and system may utilize aspects of the systems described in U.S. Pat. No. 11,242,008 and/or U.S. Publication Nos. US-2021-0162926; US-2021-0155167; US-2018-0134217 and/or US-2014-0285666, and/or International Publication No. WO 2022/150826, which are all hereby incorporated herein by reference in their entireties.

Optionally, the mirror assembly (such as at the mounting base, which may be fixed relative to the vehicle windshield) may include an imaging sensor (such as a forward facing imaging sensor or camera that has a forward field of view through the vehicle windshield) that may be part of or may provide an image output for a vehicle vision system, such as a headlamp control system or lane departure warning system or object detection system or other vehicle vision system or the like, and may utilize aspects of various imaging sensors or imaging array sensors or cameras or the like, such as a CMOS imaging array sensor, a CCD sensor or other sensors or the like, such as the types described in U.S. Pat. Nos. 5,550,677; 5,877,897; 6,498,620; 5,670,935; 5,796,094; 6,396,397; 6,806,452; 6,690,268; 7,005,974; 7,937,667; 7,123,168; 7,004,606; 6,946,978; 7,038,577; 6,353,392; 6,320,176; 6,313,454 and/or 6,824,281 which are hereby incorporated herein by reference in their entireties.

Changes and modifications in the specifically described embodiments may be carried out without departing from the principles of the present invention, which is intended to be limited only by the scope of the appended claims as interpreted according to the principles of patent law.

1. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of a cabin of a vehicle;
wherein the mirror head comprises a mirror casing and a mirror reflective element;
wherein the mirror head accommodates an electronic component;
wherein, when the electronic component is electrically operated, the electronic component generates heat within an interior cavity of the mirror head;
an aerogel-infused material disposed within the interior cavity of the mirror head, wherein the aerogel-infused material thermally conductively connects the electronic component with at least a portion of the mirror casing; and
wherein, when the electronic component is electrically operated and generates heat within the interior cavity of the mirror head, the aerogel-infused material reduces thermal transfer between the electronic component and at least the portion of the mirror casing.

2. The vehicular interior rearview mirror assembly of claim 1, wherein the electronic component comprises a video display screen.

3. The vehicular interior rearview mirror assembly of claim 1, wherein the electronic component comprises a camera.

4. The vehicular interior rearview mirror assembly of claim 1, wherein the electronic component comprises a near infrared light emitter.

5. The vehicular interior rearview mirror assembly of claim 1, wherein the aerogel-infused material thermally conductively connects with a heat sink that dissipates heat from the electronic component.

6. The vehicular interior rearview mirror assembly of claim 1, wherein the aerogel-infused material thermally conductively connects the electronic component with and a respective side portion of the mirror casing.

7. The vehicular interior rearview mirror assembly of claim 6, wherein the aerogel-infused material does not thermally conductively connect the electronic component with a central portion of the mirror casing.

8. The vehicular interior rearview mirror assembly of claim 1, wherein, when the electronic component is electrically operated, the electronic component generates sound within the interior cavity of the mirror head, and wherein the aerogel-infused material at least partially prevents sound generated by the electronic component from exiting the interior cavity of the mirror head.

9. The vehicular interior rearview mirror assembly of claim 8, wherein the electronic component comprises a cooling fan assembly.

10. The vehicular interior rearview mirror assembly of claim 8, wherein the electronic component comprises an actuator.

11. The vehicular interior rearview mirror assembly of claim 1, wherein the aerogel-infused material comprises one selected from the group consisting of (i) a foam, (ii) a paint, (iii) an adhesive and (iv) a plastic material.

12. The vehicular interior rearview mirror assembly of claim 1, wherein a heat sink is disposed between the electronic component and the aerogel-infused material, and wherein, when the electronic component is electrically operated and generates heat within the interior cavity of the mirror head, the heat sink draws heat generated by the electronic component away from the electronic component, and wherein the aerogel-infused material reduces thermal transfer between the heat sink and at least the portion of the mirror casing.

13. The vehicular interior rearview mirror assembly of claim 12, wherein the electronic component is disposed on a printed circuit board (PCB), and wherein the heat sink is in thermally conductive connection between the PCB and the aerogel-infused material.

14. The vehicular interior rearview mirror assembly of claim 1, wherein the interior portion of the cabin of the vehicle comprises a mounting button adhered to an interior surface of a windshield of the vehicle.

15. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of a cabin of a vehicle;
wherein the mirror head comprises a mirror casing and a mirror reflective element;
wherein the mirror head accommodates an electronic component;
wherein, when the electronic component is electrically operated, the electronic component generates heat within an interior cavity of the mirror head;
a heat sink thermally conductively connected to the electronic component, wherein when the electronic component is electrically operated and generates heat within the interior cavity of the mirror head, the heat sink draws heat generated by the electronic component away from the electronic component;
an aerogel-infused material disposed within the interior cavity of the mirror head, wherein the aerogel-infused material thermally conductively connects the heat sink with at least a respective side portion of the mirror casing, and wherein the aerogel-infused material does not thermally conductively connect the electronic component with a central portion of the mirror casing; and
wherein, when the electronic component is electrically operated and generates heat within the interior cavity of the mirror head, the aerogel-infused material reduces thermal transfer between the heat sink and at least the respective side portion of the mirror casing.

16. The vehicular interior rearview mirror assembly of claim 15, wherein the electronic component comprises at least one of the group consisting of (i) a video display screen, (ii) a camera and (iii) a near infrared light emitter.

17. The vehicular interior rearview mirror assembly of claim 16, wherein the aerogel-infused material comprises one selected from the group consisting of (i) a foam, (ii) a paint, (iii) an adhesive and (iv) a plastic material.

18. The vehicular interior rearview mirror assembly of claim 15, wherein the electronic component is disposed on a printed circuit board (PCB), and wherein the heat sink is in thermally conductive connection between the PCB and the aerogel-infused material.

19. The vehicular interior rearview mirror assembly of claim 15, wherein the interior portion of the cabin of the vehicle comprises a mounting button adhered to an interior surface of a windshield of the vehicle.

20. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of a cabin of a vehicle;
wherein the mirror head comprises a mirror casing and a mirror reflective element;
wherein the mirror head accommodates an electronic component, and wherein the electronic component is disposed on a printed circuit board (PCB);
wherein, when the electronic component is electrically operated, the electronic component generates heat within an interior cavity of the mirror head;
a heat sink thermally conductively connected to the PCB, wherein when the electronic component is electrically operated and generates heat within the interior cavity of the mirror head, the heat sink draws heat generated by the electronic component away from the PCB;
an aerogel-infused material disposed within the interior cavity of the mirror head, wherein the aerogel-infused material thermally conductively connects the heat sink with at least a portion of the mirror casing; and
wherein, when the electronic component is electrically operated and generates heat within the interior cavity of the mirror head, the aerogel-infused material reduces thermal transfer between the heat sink and at least the portion of the mirror casing.

21. The vehicular interior rearview mirror assembly of claim 20, wherein the electronic component comprises at least one selected from the group consisting of (i) a video display screen, (ii) a camera and (iii) a near infrared light emitter.

22. The vehicular interior rearview mirror assembly of claim 20, wherein the aerogel-infused material comprises one selected from the group consisting of (i) a foam, (ii) a paint, (iii) an adhesive and (iv) a plastic material.

23. The vehicular interior rearview mirror assembly of claim 20, wherein the interior portion of the cabin of the vehicle comprises a mounting button adhered to an interior surface of a windshield of the vehicle.
